(19) United States
(12) Patent Application Publication
(10) Pub. No.: US 2013/0293283 A1
(43) Pub. Date: Nov. 7, 2013

(54) RADIO FREQUENCY SWITCH COMPRISING HETEROJUNCTION BIOPOLAR TRANSISTORS

(71) Applicants: Moon-Suk Jeon, Seoul (KR); Chan Hoe Koo, Gyeonggi-do (KR); Hyung Bin Lee, Seoul (KR); Jung Min Oh, Seoul (KR)

(72) Inventors: Moon-Suk Jeon, Seoul (KR); Chan Hoe Koo, Gyeonggi-do (KR); Hyung Bin Lee, Seoul (KR); Jung Min Oh, Seoul (KR)

(73) Assignee: Avago Technologies Wireless IP (Singapore) Pte. Ltd., Singapore (SG)

(21) Appl. No.: 13/464,145

(22) Filed: May 4, 2012

(51) Int. Cl. H03K 17/60

(52) U.S. Cl. 327/478

(57) ABSTRACT

A radio-frequency (RF) switch comprises first and second heterojunction bipolar transistors (HBTs) that control transmission of an RF input signal between an input terminal and an output terminal. In some embodiments, the RF input signal is transmitted from the input terminal to the output terminal where the first and second HBTs are turned ON, and otherwise the RF input signal is not transmitted from the input terminal to the output terminal.

### BACKGROUND

Radio-frequency (RF) integrated circuits are commonly used in high power applications such as power amplifiers. Such circuits commonly include an RF switch capable of handling relatively large RF input signals. For example, an RF switch may be used to control transmission of RF input signals large enough to affect operating characteristics of certain components of the RF integrated circuit, e.g., by causing them to behave non-linearly.

In certain conventional implementations, the RF switch comprises a field effect transistor (FET). FETs are bidirectional devices, so they may be used effectively for RF switches receiving large signals. As examples, FIGS. 1A and 1B are circuit diagrams of conventional RF switches implemented by FETs.

Referring to FIG. 1A, a shunt switch comprises a FET connected in parallel with a path between an input terminal to an output terminal. The FET comprises a drain terminal connected to the path, a gate terminal connected to a bias circuit that drives the FET in response to a control signal, and a source terminal connected to ground.

During typical operation, the FET is turned ON or OFF in response to the control signal. Where the FET is turned ON, it shunts an RF input signal from the input terminal to ground, preventing it from being transmitted through the output terminal. For example, if the RF input signal has a positive current swing, current flows from the drain terminal to the source terminal. Similarly, if the RF input signal has a negative current swing, current flows from the source terminal to the drain terminal. Hence, none of the current passes through the output terminal. On the other hand, where the FET is turned OFF, it allows the RF input signal received at the input terminal to be transferred to the output terminal.

FIG. 1B shows a series FET switch comprising FET connected in series between an input terminal and an output terminal. The FET comprises a source terminal connected to the input terminal, a drain terminal connected to the output terminal, and a gate terminal connected to a bias circuit that drives the FET in response to a control signal.

During typical operation, the FET is turned ON or OFF in response to the control signal. Where the FET is turned on, regardless of whether an RF input signal into the source terminal has a positive current swing or a negative current swing, a current proportional to the RF input signal flows through the drain terminal such that the RF input signal is transmitted to the output terminal. However, where the FET is OFF, the RF input signal is not transmitted from the input terminal to the output terminal.

Power amplifiers commonly use a FET for the RF switch, but they often use a heterojunction bipolar transistor (HBT) due to certain benefits such as attractive manufacturing processes. For example, a power amplifier using an HBT as the RF switch may be manufactured by a so-called “heterojunction bipolar transistor (HBT) process,” which uses molecular beam epitaxy to form HBTs with highly-doped thin base layers. This process may provide high efficiency, good linearity, and low production cost. Nevertheless, RF switches comprising HBTs in the same configurations as the FETs shown in FIGS. 1A and 1B have certain drawbacks, as described below.

FIGS. 2A and 2B illustrate HBT switches with the same configurations as the FET switches shown in FIGS. 1A and 1B. The drain, gate, and source terminals of the FETs shown in FIGS. 1A and 1B correspond to collector, base, and emitter terminals of HBTs shown in FIGS. 2A and 2B, respectively.

The RF switches of FIGS. 2A and 2B operate similar to those of FIGS. 1A and 1B. However, the RF switches of FIGS. 2A and 2B are not suitable for high power applications, i.e., for large signals, because HBTs are unidirectional devices. Because HBTs are unidirectional, base currents and on-resistances are low for a positive current swing of an RF input signal while they are high for a negative current swing of the RF input signal.

### SUMMARY

Recognizing the above and other shortcomings of conventional RF switches, certain embodiments described herein provide RF switches that are implemented using HBTs having a low base current and a low on-resistance for both positive and negative current swings of an RF input signal. These characteristics may allow the RF switches to adequately handle large signals.

In an example embodiment, an RF switch is configured to control transmission of an RF input signal from an input terminal to an output terminal. The RF switch comprises a first HBT connected in parallel with a path extending between the input terminal and the output terminal and comprising an emitter terminal connected to ground and a collector terminal connected to a common terminal, and a second HBT connected in parallel with the path and comprising a collector terminal connected to ground and an emitter terminal connected to the common terminal.

In another example embodiment, an RF switch is configured to control transmission of an input RF signal from an input terminal to an output terminal. The RF switch comprises a first HBT comprising an emitter terminal connected to the input terminal and a collector terminal connected to the output terminal, and a second HBT comprising an collector terminal connected to the input terminal and an emitter terminal connected to the output terminal.

### BRIEF DESCRIPTION OF THE DRAWINGS

The example embodiments are best understood from the following detailed description when read with the accompanying drawing figures. It is emphasized that the various features are not necessarily drawn to scale. In fact, the dimensions may be arbitrarily increased or decreased for clarity of discussion. Wherever applicable and practical, like reference numerals refer to like elements.

FIGS. 1A and 1B are circuit diagrams of conventional RF switches comprising FET switches.

FIGS. 2A and 2B are circuit diagrams of conventional RF switches comprising HBT switches.

FIG. 3 is a circuit diagram of an RF switch in accordance with an example embodiment.

FIG. 4 is a waveform diagram illustrating the performance of the RF switch of FIG. 3 when the RF switch is ON in accordance with an example embodiment.

FIG. 5 is a waveform diagram illustrating differences between a voltage waveform of an ideal switch and the RF switch of FIG. 3 when both switches are ON in accordance with an example embodiment.

FIG. 6 is a graph illustrating base current consumption for the RF switch of FIG. 3 when it is ON in accordance with an example embodiment.

FIG. 7 is a circuit diagram of an RF switch in accordance with another example embodiment.

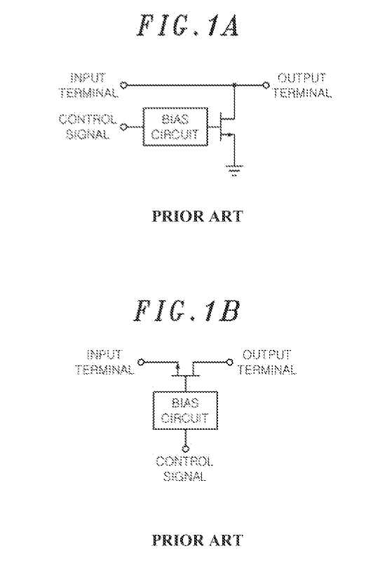

### DETAILED DESCRIPTION

In the following detailed description, for purposes of explanation and not limitation, example embodiments disclosing specific details are set forth in order to provide a thorough understanding of an embodiment according to the present teachings. However, it will be apparent to one having ordinary skill in the art having the benefit of the present disclosure that other embodiments according to the present teachings that depart from the specific details disclosed herein remain within the scope of the appended claims. Moreover, descriptions of well-known apparatuses and methods may be omitted so as to not obscure the description of the example embodiments. Such methods and apparatuses are clearly within the scope of the present teachings.

The terminology used herein is for purposes of describing particular embodiments only, and is not intended to be limiting. The defined terms are in addition to the technical and scientific meanings of the defined terms as commonly understood and accepted in the technical field of the present teachings.

As used in the specification and appended claims, the terms ‘a’, ‘an’ and ‘the’ include both singular and plural referents, unless the context clearly dictates otherwise. Thus, for example, ‘a device’ includes one device and plural devices. As used in the specification and appended claims, and in addition to their ordinary meanings, the terms ‘substantial’ or ‘substantially’ mean to within acceptable limits or degree. As used in the specification and the appended claims and in addition to its ordinary meaning, the term ‘approximately’ means to within an acceptable limit or amount to one having ordinary skill in the art. For example, ‘approximately the same’ means that one of ordinary skill in the art would consider the items being compared to be the same.

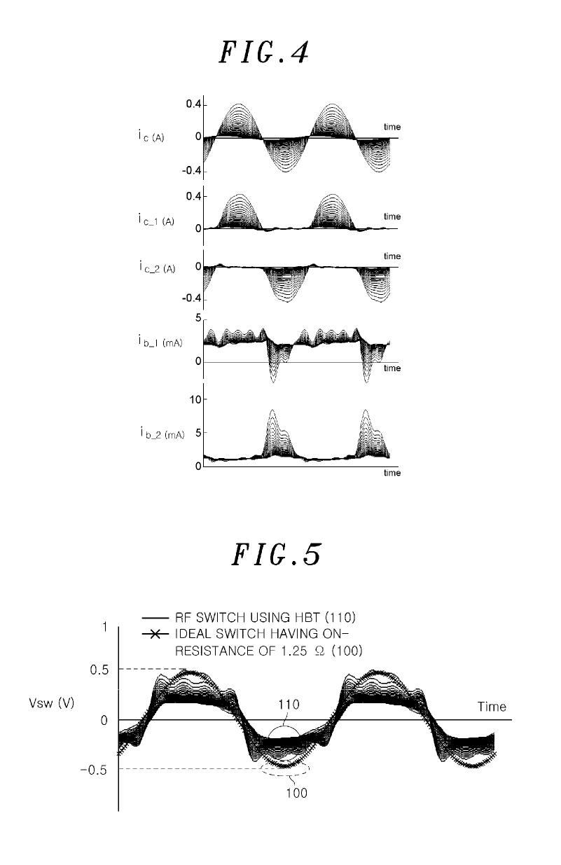

FIG. 3 is a circuit diagram of an RF switch in accordance with an example embodiment. The RF switch is a shunt RF switch comprising transistors connected in parallel with a path extending between an input terminal and an output terminal.

Referring to FIG. 3, the RF switch comprises a first HBT 10 and a second HBT 20. First HBT 10 and second HBT 20 may have a substantially the same dimensions and are arranged on a single wafer in opposite directions.

First HBT 10 has an emitter terminal connected to ground and a collector terminal connected to a common terminal C. Second HBT 20 has a collector terminal connected to ground and an emitter connected to common terminal C. Common terminal C is connected to the path between the input and the output terminals of the RF switch.

Bias circuits 30 and 40 are connected to base terminals of first HBT 10 and second HBT 20, respectively. First and second HBTs 10 and 20 are driven by bias circuits 30 and 40, respectively, and bias circuits 30 and 40 operate in response to a control signal from a control circuit 50. Where both of first and second HBTs 10 and 20 are ON, the RF switch is turned ON. That is, the common terminal is substantially grounded when the HBTs are ON, allowing an RF input signal at the input terminal to flow to the ground, and not transferring the input signal to the output terminal. Bias circuits 30 and 40 receive the same control signal from control circuit 50.

FIG. 4 is a waveform diagram illustrating the performance of the RF switch of FIG. 3 when the RF switch is ON in accordance with an example embodiment.

Referring to FIG. 4, where the shunt RF switch is ON (i.e., both of first and second HBTs 10 and 20 are ON), where the RF input signal into common terminal C has a positive current swing with respect to first HBT 10 (i.e., a common collector current i_{c} has a positive value), first HBT 10 operates to draw a first collector current i_{c}_{_{—}}₁ with a first base current i_{b}_{_{—}}₁ having low current swings and the RF switch exhibits a low on-resistance. Under these circumstances, a second collector current i_{c}_{_{—}}₂ of second HBT 20 remains substantially zero. In contrast, where the RF input signal into the common terminal has a negative current swing with respect to first HBT 10 (i.e., the common collector current i_{c} has a negative value), because the RF input signal is of a positive current swing with respect to second HBT 20, and, therefore, second HBT 20 operates to draw a second collector current i_{c}_{_{—}}₂ with a second base current i_{b}_{_{—}}₂ having low current swings and the RF switch still exhibits the low on-resistance. Meanwhile, the first collector current i_{c}_{_{—}}₁ for first HBT 10 remains substantially zero.

Where the RF switch is OFF (i.e., both of first and second HBTs 10 and 20 are OFF), first and second HBTs 10 and 20 do not draw current, and the RF input signal is transferred to the output terminal through the path.

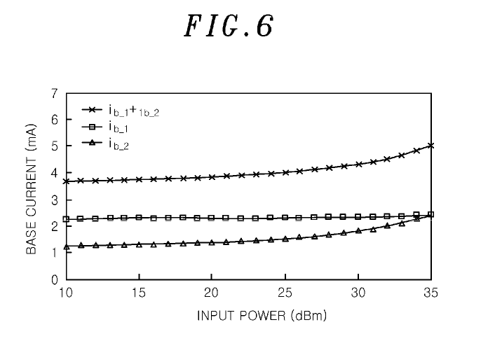

FIG. 5 is a waveform diagram illustrating differences between a voltage waveform of an ideal switch and the RF switch of FIG. 3 when both switches are ON in accordance with an example embodiment.

Referring to FIG. 5, voltage waveforms 100 and 110 represent time varying voltages for an ideal RF switch and the RF switch of FIG. 3, where the input current has a peak value of 400 mA. Where the RF switch shown in FIG. 3 is ON, even if the input current rises to 400 mA, a voltage ripple V_{sw} at common terminal C does not exceed 0.5V. This is similar to a waveform of a voltage ripple of the ideal RF switch having a on-resistance of 1.25 ohm. In other words, where first and second HBTs 10 and 20 are ON, for such a high input power, the on-resistance of the RF switch of the preferred embodiment remains below 1.25 ohm.

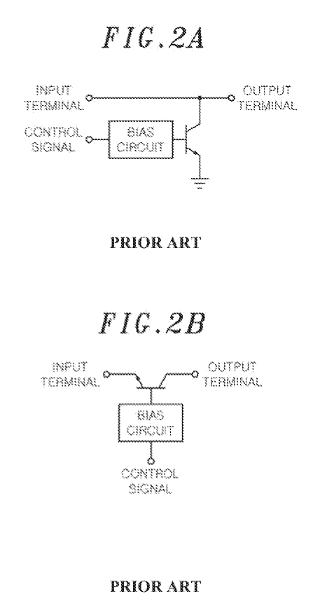

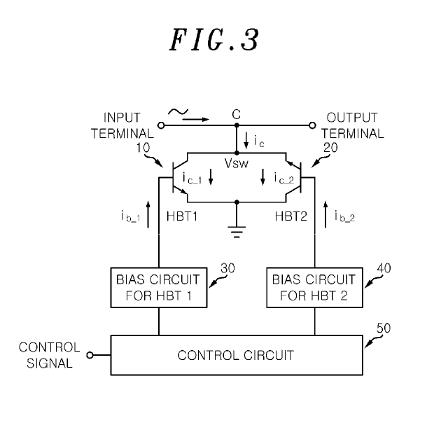

As illustrated by FIG. 5, the RF switch of FIG. 3 is suitable for large signals because it exhibits a low base current and a low on-resistance for both the positive and the negative current swings of the RF input signal, unlike the switch shown in FIG. 2A or 2B.

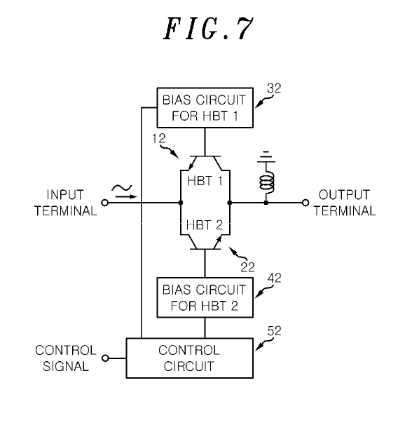

FIG. 6 is a graph illustrating base current consumption for the RF switch of FIG. 3 when it is ON in accordance with an example embodiment. In particular, FIG. 6 illustrates base current consumption of first and second HBTs 10 and 20 over an input power when the shunt RF switch of FIG. 3 is ON.

Referring to FIG. 6, the shunt RF switch of FIG. 3, when turned ON, exhibits approximately 5 mA of a total base current consumption i_{b1}+i_{b2} for the input current having a peak value of 400 mA and a power of 35 dBm. Such an amount of the total base current consumption does not significantly deteriorate overall system efficiency in a circuit that employs high value of power such as 35 dBm, meaning that the RF switch may be suitable for high power applications.

FIG. 7 is a circuit diagram of an RF switch in accordance with another example embodiment. The RF switch of FIG. 7 is of a series RF switch which is connected in series to a path extending from an input terminal to an output terminal.

Referring to FIG. 7, the RF switch comprises a first HBT 12 and a second HBT 22. First HBT 12 and second HBT 22 have substantially the same dimensions and are formed in the same wafer in opposite directions.

An emitter terminal of first HBT 12 and a collector terminal of second HBT 22 are connected to the input terminal while a collector terminal of first HBT 12 and an emitter terminal of second HBT 22 are connected to the output terminal. Based on this configuration, when the RF switch is ON, an RF input signal at the input terminal is transferred to the output terminal.

First and second HBTs 12 and 22 are driven by bias circuits 32 and 42 connected to base terminals thereof, respectively, and the bias circuits 32 and 42 operate based on a control signal. In one example, the bias circuits 32 and 42 may receive a same control signal from a single control circuit 52.

Where the RF switch is ON (i.e., both of first and second HBTs 12 and 22 are ON), for a negative current swing of the RF input signal with respect to first HBT 12 (i.e., a positive current swing with respect to second HBT 22), second HBT 22 draws a collector current and an output current having substantially the same amplitude as that of an input current is output to the output terminal via the emitter terminal of second HBT 22. On the other hand, for a positive current swing of the RF input signal with respect to first HBT 12, first HBT 12 flows an emitter current (i.e., receives an input current) at the input terminal and draws a collector current (i.e., outputs an output current) from the output terminal. As a consequence, similar to the RF switch of FIG. 3, the series RF switch exhibits a low base current and a low on-resistance for both the positive and the negative current swings of the RF input signal, and, thus, is suitable for large signals.

While example embodiments are disclosed herein, one of ordinary skill in the art appreciates that many variations that are in accordance with the present teachings are possible and remain within the scope of the appended claims. The embodiments therefore are not to be restricted except within the scope of the appended claims.

1. A radio-frequency (RF) switch configured to control transmission of an RF input signal from an input terminal to an output terminal, comprising:
a first heterojunction bipolar transistor (HBT) connected in parallel with a path extending between the input terminal and the output terminal and comprising an emitter terminal connected to ground and a collector terminal connected to a common terminal; and
a second HBT connected in parallel with the path and comprising a collector terminal connected to ground and an emitter terminal connected to the common terminal.

2. The RF switch of claim 1, wherein the common terminal is connected to the input terminal and the output terminal.

3. The RF switch of claim 1, further comprising first and all second bias circuits connected to base terminals of the first HBT and the second HBT, respectively, wherein the RF switch is turned ON as a consequence of the first HBT and the second HBT being turned ON by the first and the second bias circuits.

4. The RF switch of claim 3, wherein the first and the second bias circuits operate in response to a same control signal input from a control circuit.

5. The RF switch of claim I, wherein the first and the second HBTs are formed on a single wafer and arranged in opposite directions.

6. The RF switch of claim 1, wherein the RF input signal is transmitted from the input terminal to the output terminal where the first and second HBTs are turned OFF, and otherwise the RF input signal is not transmitted from the input terminal to the output terminal.

7. A radio-frequency (RF) switch configured to control transmission of an input RF signal from an input terminal to an output terminal, comprising:
a first heterojunction bipolar transistor (HBT) comprising an emitter terminal connected to the input terminal and a collector terminal connected to the output terminal; and
a second HBT comprising an collector terminal connected to the input terminal and an emitter terminal connected to the output terminal.

8. The RF switch of claim 7, further comprising first and second bias circuits connected to base terminals of the first HBT and the second HBTs, respectively,
wherein the RF switch is ON as a consequence of the first HBT and the second HBT being turned ON in response to the first and the second bias circuits.

9. The RF switch of claim 8, wherein the first and the second bias circuits operate based on a same control signal input from a single control circuit.

10. The RF switch of claim 7, wherein the first and the second HBTs are formed on a single wafer and arranged in opposite directions.

11. The RF switch of claim 7, wherein the RF input signal is transmitted from the input terminal to the output terminal where the first and second HBTs are turned ON, and otherwise the RF input signal is not transmitted from the input terminal to the output terminal.
